(19) United States
(12) Patent Application Publication
(10) Pub. No.: US 2026/0165207 A1
(43) Pub. Date: Jun. 11, 2026

(54) ISOLATION PITS FOR MITIGATING MIGRATION OF CONDUCTIVE MATERIALS IN STACKED SEMICONDUCTOR DEVICES AND ASSOCIATED SYSTEMS AND METHODS

(71) Applicant: Micron Technology, Inc., Boise, ID (US)

(72) Inventors: Udit Narula, Meridian, ID (US); Nancy Lomeli, Boise, ID (US)

(21) Appl. No.: 19/360,862

(22) Filed: Oct. 16, 2025

Related U.S. Application Data
(60) Provisional application No. 63/729,952, filed on Dec. 9, 2024.

(51) Int. Cl. H01L 23/00; H01L 25/065

(52) U.S. Cl. CPC H10W 90/00; H10W 72/01955; H10W 72/923; H10W 72/932; H10W 80/312; H10W 80/327; H10W 80/334; H10W 90/26; H10W 90/792

(57) ABSTRACT

Systems and methods for mitigating migration of conductive material in stacked semiconductor devices are disclosed herein. For example, a stacked semiconductor device according to the present technology can include a first die and a second die carried by and bonded to the first die. The first die has a first bonding surface and includes a first bond pad, a second bond pad spaced apart from the first bond pad, and a migration isolation pit. The migration isolation pit is positioned between the first bond pad and the second bond pad. The second die has a second bonding surface and includes a third bond pad bonded to the first bond pad and a fourth bond pad bonded to the second bond pad. In some embodiments, the second die also includes a migration isolation pit positioned between the third bond pad and the fourth bond pad.

### CROSS-REFERENCE TO RELATED APPLICATION(S)

The present application claims priority to U.S. Provisional Patent Application No. 63/729,952, filed Dec. 9, 2024, the disclosure of which is incorporated herein by reference in its entirety.

### TECHNICAL FIELD

The present technology is generally directed to systems and methods for addressing electrical shorts in stacked semiconductor devices and more specifically to isolation pits for mitigating the migration of conductive material in stacked semiconductor devices.

### BACKGROUND

An electronic apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM) and/or high-bandwidth memory (HBM), can utilize electrical energy to store and access data.

With technological advancements in embedded systems and increasing applications, the market is continuously looking for faster, more efficient, and smaller devices. To meet the market demands, the semiconductor devices are being pushed to the limit with various improvements. Improving devices, generally, may include increasing circuit density, increasing circuit capacity, increasing operating speeds (or otherwise reducing operational latency), increasing reliability, increasing data retention, reducing power consumption, or reducing manufacturing costs, among other metrics. Attempts, however, to meet the market demands, such as by reducing the overall device footprint, can often introduce challenges in other aspects, such as maintaining circuit robustness and/or failure detectability.

### BRIEF DESCRIPTION OF THE DRAWINGS

FIG. 1 is a partially schematic cross-sectional view of a stacked semiconductor device configured in accordance with embodiments of the present technology.

FIG. 2 is a partially schematic top view of a semiconductor die configured in accordance with embodiments of the present technology.

FIG. 3 is a partially schematic top view of a semiconductor die configured in accordance with embodiments of the present technology.

FIGS. 4A-4F are partially schematic cross-sectional views of a semiconductor die at various stages of manufacturing in accordance with embodiments of the present technology.

FIG. 5 is a flow diagram of a process for manufacturing a stacked semiconductor device in accordance with embodiments of the present technology.

The drawings have not necessarily been drawn to scale. Similarly, some components and/or operations can be separated into different blocks or combined into a single block for the purpose of discussion of some of the implementations of the present technology. Moreover, while the technology is amenable to various modifications and alternative forms, specific implementations have been shown by way of example in the drawings and are described in detail below. The intention, however, is not to limit the technology to the particular implementations described.

### DETAILED DESCRIPTION

Stacked semiconductor devices that include features for mitigating migration of conductive material (e.g., copper from bond pads in the stacked semiconductor dies) and associated systems and methods are disclosed herein. For example, a stacked semiconductor device according to the present technology can include a first semiconductor die and a second semiconductor die bonded to the first semiconductor die. The first semiconductor die can include a plurality of bond pads, as well as one or more migration isolation pits at a first bonding surface. Similarly, the second semiconductor die can include a plurality of bond pads that are bonded to a corresponding bond pad from the first semiconductor die (e.g., via metal-metal bonds). Each of the migration pit(s) is positioned between a pair of adjacent bond pads. As a result, the migration isolation pit(s) can absorb conductive material (e.g., copper) migrating out of the bond pads (e.g., in response to thermal, electrical, and/or mechanical stress). By absorbing the migrating material, the migration isolation pit(s) can help prevent the conductive material from forming electrical shorts between adjacent bond pads. That is, the migration isolation pit(s) can help mitigate deleterious effects of the conductive material migration, thereby improving a quality of the stacked semiconductor device (e.g., reducing the number of shorts) and/or extending a lifespan of the stacked semiconductor device.

As used herein, the terms “vertical,” “lateral,” “upper,” “lower,” “top,” and “bottom” can refer to relative directions or positions of features in the SiP devices in view of the orientation shown in the drawings. For example, “bottom” can refer to a feature positioned closer to the bottom of a page than another feature. These terms, however, should be construed broadly to include semiconductor devices having other orientations, such as inverted or inclined orientations where top/bottom, over/under, above/below, up/down, and left/right can be interchanged depending on the orientation. Additionally, it will be understood that the stacked semiconductor devices described herein can implemented in a variety of semiconductor packages. For example, a stack of semiconductor dies can be implemented in a dynamic random-access memory (DRAM), a high-bandwidth memory (HBM), a system-in-package (SiP) device, and/or a variety of other memory devices. In another example, the stacked semiconductor dies described herein can be stacked logic and/or processing dies.

Further, although primarily discussed herein in the context of mitigating migration of conductive material between electrically conductive bond pads of a stacked semiconductor device, one of skill in the art will understand that the scope of the invention is not so limited. For example, the isolation pits described herein can be positioned between bond pads on various other substrates (e.g., package substrates, base substrates, interposer substrates, and/or the like). In another example, the isolation pits can be positioned between other electrically conductive features (e.g., route lines) that experience migration. In yet another example, the isolation pits can be formed between thermally conductive features (e.g., bond pads of thermal through substrate vias) to help reduce thermal shorts in a stacked semiconductor device. Accordingly, the scope of the invention is not confined to any subset of embodiments and is confined only by the limitations set out in the appended claims.

Still further, unless the context indicates otherwise, structures disclosed herein can be formed using one or more semiconductor-manufacturing techniques. Materials can be deposited, for example, using chemical vapor deposition (CVD), physical vapor deposition (PVD), atomic layer deposition (ALD), spin coating, plating, and/or other suitable techniques. Similarly, materials can be removed, for example, using plasma etching, wet etching, chemical-mechanical planarization, or other suitable techniques. Some of the techniques may be combined with photolithography processes. The term “semiconductor device or die” generally refers to a solid-state device that includes one or more semiconductor materials. Examples of semiconductor devices include logic devices, memory devices, controllers, or microprocessors (e.g., central processing unit (CPU), graphics processing unit (GPU)), among others. Such semiconductor devices may include integrated circuits or components, data storage elements, processing components, and/or other features manufactured on semiconductor substrates. Additionally, a person having ordinary skill in the relevant art will recognize that suitable steps of the methods described herein can be performed at the wafer level or at the die level.

Smaller footprints, increased density, and increased lifespans are features that are demanded in stacked semiconductor devices. To meet these demands, a base substrate (e.g., printed circuit boards, other prepreg substrates, silicon substrates, and/or the like) can be manufactured with a variety of metallization structures (e.g., external-facing bond pads, route lines and other metallization layers, internal bond pads and bond fingers, and/or the like). A plurality of semiconductor dies (e.g., memory dies, logic dies, controller dies, interposer dies, routing dies, and/or any other dies) and/or other semiconductor components (e.g., PHY layers, interposers, and/or the like) can then be stacked on the base substrate and connected to the base substrate via metal-metal bonds, through substrate vias (TSVs), and/or the like. The stack allows the semiconductor device to include additional memory, functionality, processing power, and/or the like into the same longitudinal footprint.

However, the process of bonding components of the stacked semiconductor devices and the operation of the semiconductor devices apply electrical, mechanical, and thermal stresses to the stacked semiconductor device. The stresses can cause conductive material in the bond pads in the stacked components of the semiconductor devices (e.g., in the semiconductor dies) to migrate (electromigration and/or stress migration). In turn, the migration can create various deleterious effects in the stacked semiconductor device such as short circuits between adjacent bond pads that undermine (or fully destroy) the functionality of the stacked semiconductor device.

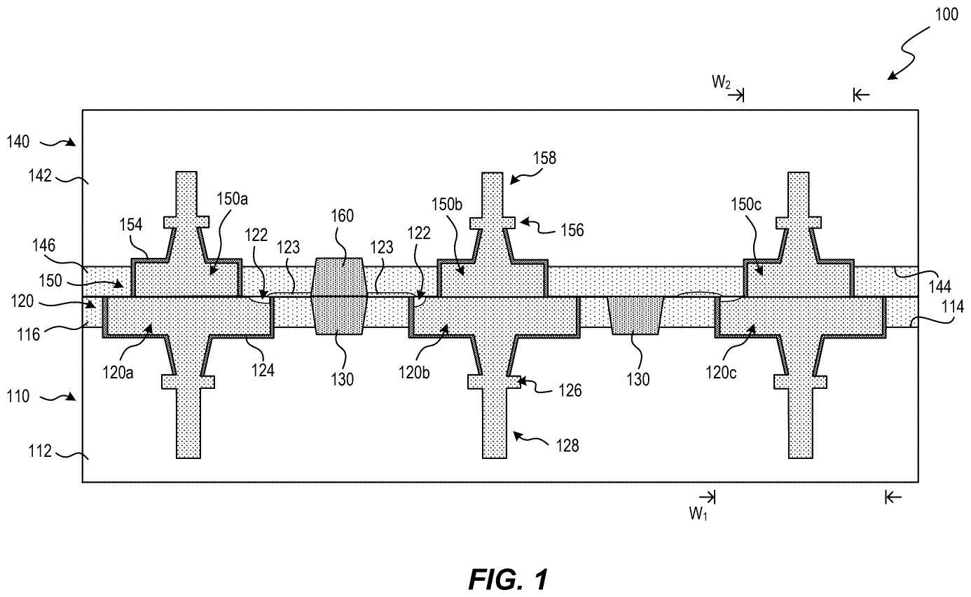

The systems and methods disclosed herein address the problems discussed above by forming one or more migration isolation pits in the bonding surfaces of the semiconductor dies (or other components) in a stacked semiconductor device between adjacent bond pads. As discussed in more detail below, the migration isolation pits can act like a sponge for migrating conductive material. As a result, the migration isolation pits can help break a lamella of the conductive material and reduce the chance that the migrating conductive material can form a short circuit between adjacent bond pads. Said another way, the migration isolation pits can help mitigate the deleterious effects of the migration. As a result, the migration isolation pits can help improve the stacked semiconductor device's ability to withstand electrical, mechanical, and/or thermal stresses. Further, in some embodiments, by breaking the lamella, the migration isolation pits can help increase the surface area of the dielectric material available to form dielectric-dielectric bonds. As a result, the migration isolation pits can help improve a bond strength of the stacked semiconductor devices. Additional details on the migration isolation pits, the process of forming the migration isolation pits, as well as the resulting stacked semiconductor devices, are discussed in more detail below with reference to FIGS. 1-5.

FIG. 1 is a partially schematic cross-sectional view of a stacked semiconductor device 100 configured in accordance with embodiments of the present technology. In the illustrated embodiment, the stacked semiconductor device 100 includes a first semiconductor die 110 and a second semiconductor die 140 carried by and bonded to the first semiconductor die 110. The first semiconductor die 110 (sometimes also referred to herein as a “die”) includes a base substrate 112 that has a bonding surface 114, as well as a dielectric layer 116 formed on the bonding surface 114 (e.g., a dielectric layer at the bonding surface of the first semiconductor die 110). The first semiconductor die 110 also includes a plurality of conductive features. For example, in the illustrated embodiments, the first semiconductor die 110 includes a plurality of bond pads 120 (three illustrated in FIG. 1, referred to individually as “first-third bond pads 120a-120c”) and a barrier layer 124 formed around each of the plurality of bond pads 120. The first semiconductor die 110 can also include various metallization features formed within the base substrate 112 that are communicably coupled to the plurality of bond pads 120. For example, the first semiconductor die 110 can include one or more metallization layers 126 (e.g., metallization lines, a redistribution layer, circuits, and/or the like) that form signal lines and/or active circuits for the first semiconductor die 110. Additionally, or alternatively, the first semiconductor die 110 can include a plurality of TSVs 128, each of which is communicably coupled to one or more of the plurality of bond pads 120 and/or the metallization layers 126 to provide a signal path through the base substrate 112.

Similarly, as illustrated in FIG. 1, the second semiconductor die 140 includes a base substrate 142, a dielectric layer 146 formed at a bonding surface 144 of the base substrate 142, and a plurality of conductive features. More specifically, the second semiconductor die 140 includes a plurality of bond pads 150 (three illustrated in FIG. 1, referred to individually as “first-third bond pads 150a-150c”), a barrier layer 154 formed around each of the plurality of bond pads 150, as well as one or more metallization layers 156 and a plurality of TSVs 158 communicatively coupled to the plurality of bond pads 150.

As further illustrated in FIG. 1, the bond pads 120 in the first semiconductor die 110 are not perfectly aligned with the bond pads 150 in the second semiconductor die 140. In the illustrated embodiments, the lack of alignment results from a different size between the bond pads 120 in the first semiconductor die 110 and the bond pads 150 in the second semiconductor die 140. More specifically, each of the first-third bond pads 120a- 120c in the first semiconductor die 110 has a first width W₁ (e.g., a first diameter and/or cross-sectional width) while each of the first-third bond pads 120a- 150c in the second semiconductor die 140 has a second width W₂ that is smaller than the first width W₁. As a result, a portion of an outer surface of each of the first-third bond pads 120a- 120c in the first semiconductor die 110 is exposed (e.g., not bonded and/or not surrounded by a barrier layer). The exposed portions can additionally, or alternatively, result from errors in the alignment between the first semiconductor die 110 and the second semiconductor die 140. That is, errors in the alignment can also expose portions of the bond pads 120 in the first semiconductor die 110 and/or portions of the bond pads 150 in the second semiconductor die 140, even when the bond pads have a generally equal size.

The exposed portions of the bond pads, in turn, can be sources of stress migration and/or electromigration during the construction and/or operation of the stacked semiconductor device 100 (e.g., in response to thermal, mechanical, and/or electrical stresses). More specifically, in the illustrated embodiments, a portion of the conductive material in the bond pads 120 (e.g., copper, gold, and/or any other suitable metal) can migrate across (e.g., horizontally across) a bonding interface between the first semiconductor die 110 and the second semiconductor die 140. The migration, as illustrated in FIG. 1, can result in cavities 122 in the bond pads 120 and a lamella 123 of conductive material extending away from the bond pads 120. As discussed above, the lamella 123 (sometimes also referred to as “segments,” “migration arms,” and/or the like”), if not addressed, can form a short circuit between adjacent bond pads, thereby undermining (or destroying) a functionality of the stacked semiconductor device 100.

As further illustrated in FIG. 1, the stacked semiconductor device 100 can also include features that help mitigate the migration of conductive materials. For example, the first semiconductor die 110 can include first migration isolation pits 130 that are formed in the dielectric layer 116 and the base substrate 112 between adjacent pairs of the plurality of bond pads 120. For example, the first semiconductor die 110 includes at least one of the first migration isolation pits 130 between the first and second bond pads 120a, 120b (one in the embodiments illustrated in FIG. 1). Further, the first semiconductor die 110 includes at least one of the first migration isolation pits 130 between the second and third bond pads 120b, 120c (one in the embodiments illustrated in FIG. 1). Similarly, the second semiconductor die 140 can include second migration isolation pits 160 that are formed in the dielectric layer 146 and the base substrate 142 between adjacent pairs of the plurality of bond pads 150. For example, the second semiconductor die 140 includes at least one of the second migration isolation pits 160 between the first and second bond pads 150a, 150b (one in the embodiments illustrated in FIG. 1).

As discussed in more detail below, the first migration isolation pits 130 can include a trench formed into the dielectric layer 116 and at least a portion of the base substrate 112, as well as a non-conductive material filling the trench. Similarly, the second migration isolation pits 160 can include a trench formed into the dielectric layer 146 and at least a portion of the base substrate 142, as well as a non-conductive material filling the trench. The non-conductive material in each of the first and second migration isolation pits 130, 160 can be a second dielectric material (e.g., different from the dielectric material in the dielectric layers 116, 146). For example, the non-conductive material in each of the first and second migration isolation pits 130, 160 can include various Silicon Oxides (SiOₓ), Silicon Nitrides (SiₓN_{y}), a low-Carbon Silicon Carbon Nitride (SiCN) (e.g., a SiCN material with less carbon than stoichiometrically neutral), and/or various other low (or no) Carbon dielectrics.

While the reduction of carbon in the non-conductive material (or complete omission) can reduce the bonding strength at the bonding interface, the reduction (or omission) of carbon allows the first and second migration isolation pits 130, 160 to absorb conductive materials (e.g., copper, gold, solder, and/or the like) migrating across the bonding interface. As a result, the first and second migration isolation pits 130, 160 can act like a sponge for the migrating material and diffuse the migrating materials within the pits such that the migrating materials do not continue to migrate along the bonding interface. Said another way, by absorbing the migrating conductive materials the first and second migration isolation pits 130, 160 can break the lamella 123. As a result, first and second migration isolation pits 130, 160 can help prevent short circuits from forming between the adjacent bond pads. That is, the first and second migration isolation pits 130, 160 can help mitigate the deleterious effects of the migration of the conductive materials. Further, the first and second migration isolation pits 130, 160 can occupy a relatively small portion of the bonding interface such that the reduction in the bond strength is minimal.

In some embodiments, the first semiconductor die 110 and the second semiconductor die 140 both include the migration isolation pits (the first and second migration isolation pits 130, 160, respectively). However, the technology disclosed herein is not so limited. In some embodiments, a single isolation pit is sufficient to absorb migrating conductive materials and/or to mitigate the deleterious effects of the migration. For example, as further illustrated in FIG. 1, the first semiconductor die 110 includes one of the first migration isolation pits 130 between the second and third bond pads 120b, 120c while the second semiconductor die 140 does not include one of the second migration isolation pits 160 between the second and third bond pads 150b, 150c. The omission of the isolation pits from one of the first and second semiconductor dies 110, 140 can help reduce manufacturing costs while obtaining at least a portion of the mitigating benefits of the migration isolation pits.

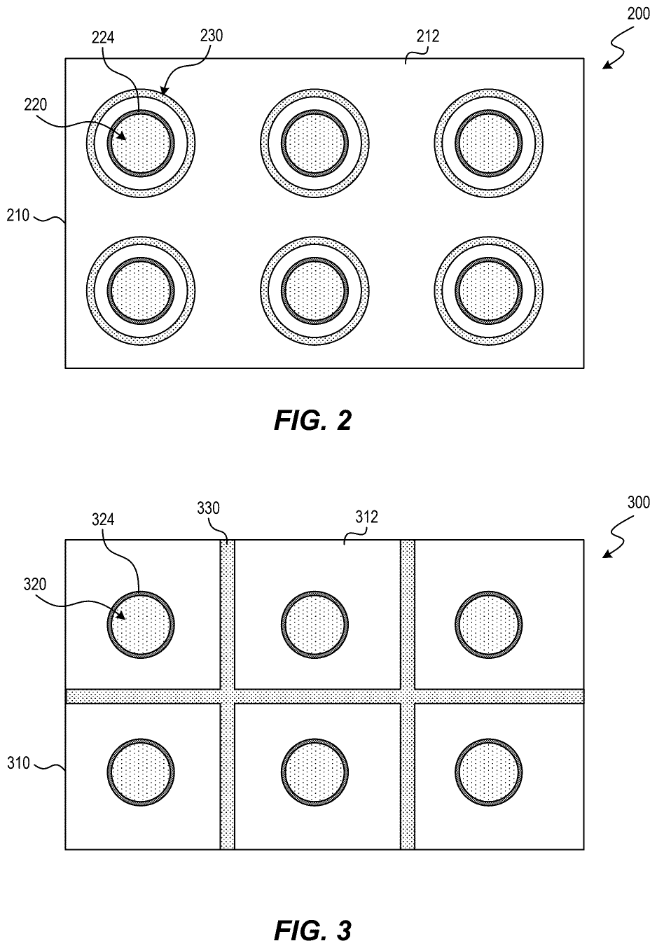

FIG. 2 is a partially schematic top view of a semiconductor die 200 configured in accordance with embodiments of the present technology. In the illustrated embodiments, the semiconductor die 200 is generally similar to the semiconductor dies discussed above with reference to FIG. 1. For example, the semiconductor die 200 includes a base substrate 210 and a plurality of bond pads 220 (six shown in FIG. 2) at a bonding surface 212 of the base substrate 210. Each of the bond pads 220 is surrounded by a barrier material 224. Further, the semiconductor die 200 also includes a plurality of migration isolation pits 230, with each pair of adjacent bond pads 220 having at least one of the migration isolation pits 230 positioned therebetween. Said another way, each of the bond pads 220 is spaced apart from each other bond pad by at least one of the migration isolation pits 230.

In the illustrated embodiments, each of the migration isolation pits 230 fully surrounds (e.g., forms a perimeter around, circumscribes, fully isolates, and/or the like) a corresponding one of the bond pads 220. That is, each of the migration isolation pits 230 includes a trench formed fully around a corresponding one of the bond pads 220 and a non-conductive material filling the trench. As a result, each of the bond pads 220 is spaced apart from the other bond pads by two of the migration isolation pits 230 (e.g., the migration isolation pit surrounding an individual bond pad and the migration isolation pit surrounding another individual bond pad).

However, it will be understood that, in various other embodiments, the migration isolation pits 230 can partially surround (e.g., form partial perimeters around) the bond pads 220 and/or that the migration isolation pits 230 can surround alternating ones of the bond pads 220. Purely by way of example, the semiconductor die 200 can include the migration isolation pits 230 fully surrounding the top left, top right, and bottom middle bond pads 220. As a result, each pair of adjacent bond pads includes one of the migration isolation pits 230 positioned therebetween with less impact on a bond strength at the bonding surface 212 than the embodiments illustrated in FIG. 2. In another example, each of the migration isolation pits 230 can include segments positioned between adjacent bond pads 220 without fully enclosing any of the bond pads 220.

Further, in the embodiments illustrated in FIG. 2, the bond pads 220 and the migration isolation pits 230 each have a circular cross-sectional shape. It will be understood, however, that the technology disclosed herein is not so limited. For example, in various embodiments, the bond pads 220 and/or the migration isolation pits 230 can have an ovular cross-sectional shape, a square (and/or rectangular) cross-sectional shape, a hexagonal cross-sectional shape, and/or any other suitable cross-sectional shape.

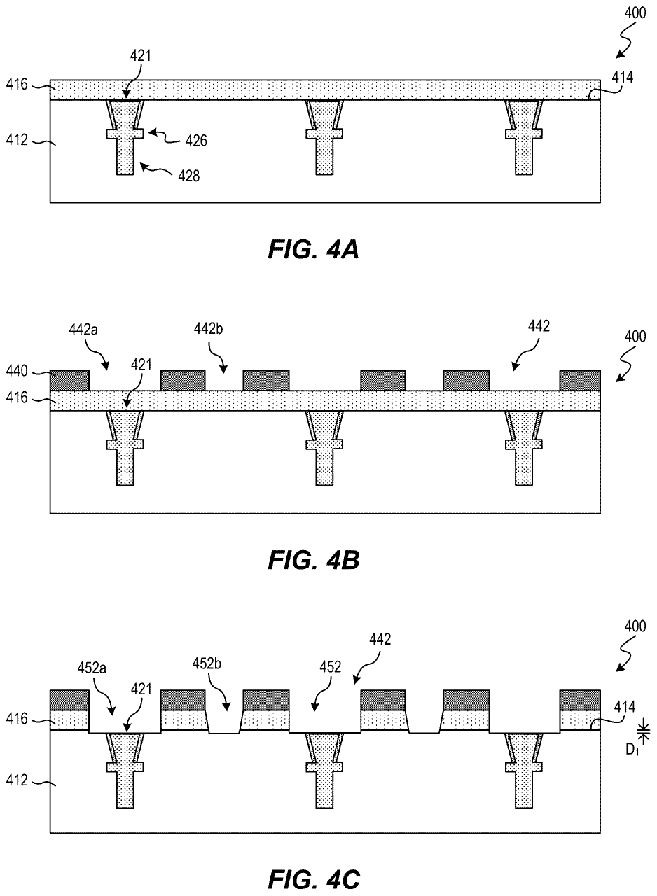

FIG. 3 is a partially schematic top view of a semiconductor die 300 configured in accordance with embodiments of the present technology. In the illustrated embodiments, the semiconductor die 300 is generally similar to the semiconductor die 200 discussed above with reference to FIG. 2. For example, the semiconductor die 300 includes a base substrate 310 and a plurality of bond pads 320 (six shown in FIG. 3) at a bonding surface 312 of the base substrate 310. Further, each of the bond pads 320 is surrounded by a barrier material 324. Still further, the semiconductor die 300 also includes a migration isolation pit 330 positioned between each pair of adjacent bond pads 320. Said another way, each of the bond pads 320 is spaced apart from each other bond pad by at least a portion of the migration isolation pit 330.

In the illustrated embodiments, however, the migration isolation pit 330 forms grid lines around each of the bond pads 320 such that the bond pads 320 are formed in the open spaces of the grid. Said another way, each of the bond pads 320 is spaced apart from the other bond pads by one or more rows and/or columns of the grid defined by the migration isolation pits 330. Said yet another way, the migration isolation pit 330 includes a grid of trenches isolating the bond pads 320 and a non-conductive material filling the trenches. The grid line configuration of the migration isolation pit 330 can help simplify manufacturing while ensuring that each pair of adjacent bond pads is spaced apart by at least one grid line of the migration isolation pit 330. While the migration isolation pit 330 illustrated in FIG. 3 forms a generally continuous pit, it will be understood that the migration isolation pit 330 can be separated into multiple pits. Purely by way of example, the migration isolation pit 330 can be separated into segments (e.g., dashed grid lines) with a segment positioned along a direct line between adjacent bond pads 320. Further, while specific examples of patterns and shapes of the migration isolation pits have been discussed above with reference to FIGS. 2 and 3, it will be understood that the migration isolation pit(s) can have any other suitable shape and/or pattern.

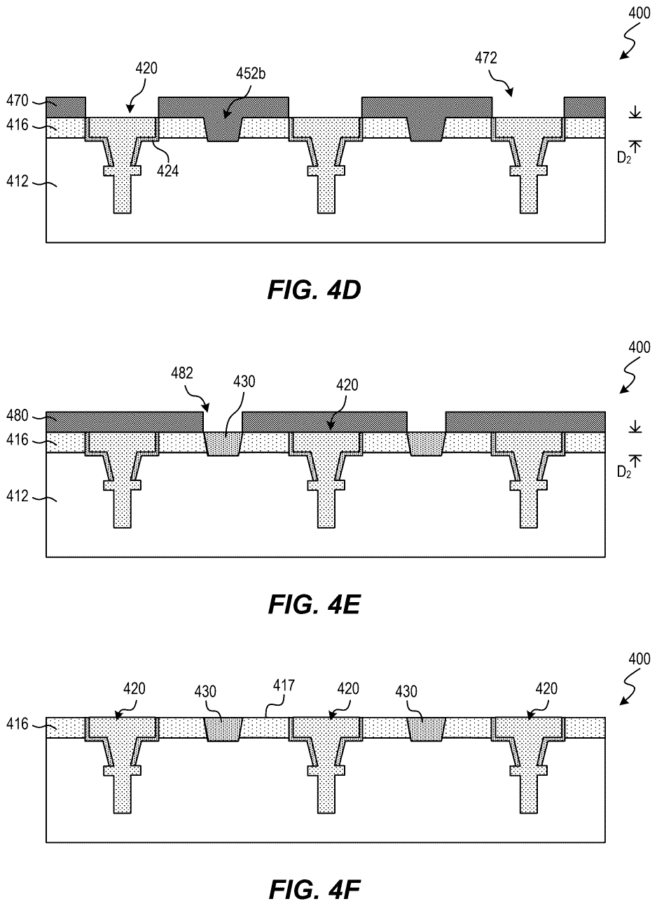

FIGS. 4A-4F are partially schematic cross-sectional views of a semiconductor die 400 at various stages of manufacturing in accordance with embodiments of the present technology. More specifically, FIGS. 4A-4F illustrate an example of a process for manufacturing the semiconductor die 400 to include one or more migration isolation pits similar to those discussed above with reference to FIGS. 1-3.

FIG. 4A illustrates the semiconductor die 400 at the start of the process (or subprocess). As illustrated in FIG. 4A, the semiconductor die 400 can be generally similar to the semiconductor dies discussed above. For example, the semiconductor die 400 can include a base substrate 412, as well as a dielectric layer 416 (e.g., SiCN and/or another suitable dielectric) deposited over a bonding surface 414 of the base substrate. Further, the semiconductor die 400 can include one or more metallization layers 426 and one or more TSVs 428 formed in the base substrate (sometimes collectively referred to herein as “metallization features” and/or “conductive features” formed within the base substrate). As further illustrated in FIG. 4A, the semiconductor die 400 at the start of the process does not include bond pads at the bonding surface 414. Instead, upper surfaces 421 of the metallization features formed within the base substrate 412 are covered by the dielectric layer 416.

FIG. 4B illustrates the semiconductor die 400 after a first masking layer 440 (e.g., a photo-etchable material) is formed on the dielectric layer 416 and patterned. As illustrated in FIG. 4B, the patterning process forms openings 442 in the first masking layer 440 that expose portions of the dielectric layer 416. Further, the openings 442 include a plurality of first openings 442a that are vertically aligned with the upper surfaces 421 of the metallization features, as well as a plurality of second openings 442b that are positioned between pairs of adjacent first openings 442a.

FIG. 4C illustrates the semiconductor die 400 after an etching process through the openings 442 in the first masking layer 440. The etching process can remove the dielectric layer 416 exposed by the openings 442, as well as a portion of the base substrate 412 beneath the dielectric layer 416. As a result, the semiconductor die 400 includes a plurality of openings 452. Similar to the discussion above, the openings 452 can include a plurality of first openings 452a that expose the upper surfaces 421 of the metallization features, as well as a plurality of second openings 452b (sometimes also referred to herein as “trenches”) that are positioned between pairs of adjacent first openings 452a. In the illustrated embodiment, each of the openings 452 is formed to a first depth D₁ within the base substrate 412. By forming the openings 452 to the first depth, the etching process can help ensure that the upper surfaces 421 are fully exposed (e.g., to help form electric bonds with bond pads in the processes discussed below).

FIG. 4D illustrates the semiconductor die 400 after forming bond pads 420 over the upper surfaces 421 (FIG. 4C) of the metallization features. To form the bond pads 420, the process can include stripping (or otherwise removing) the first masking layer 440 (FIG. 4B), depositing a second masking layer 470 over the dielectric layer 416, and etching the second masking layer 470 to include a plurality of openings 472. In contrast to the openings discussed above, the openings 472 in the second masking layer 470 are only formed in locations corresponding to the bond pads 420 (e.g., only over the upper surfaces 421 (FIG. 4C) and/or only over the first openings 452a (FIG. 4C) in the semiconductor die 400). As a result, for example, the second openings 452b in the semiconductor die 400 are filled with the second masking layer 470. Once the openings 472 are formed, the process can include forming a barrier layer 424 and filling the remainder of the openings 472 with a conductive material (e.g., copper, a gold layer, and/or any other suitable material) to form the bond pads 420.

FIG. 4E illustrates the semiconductor die 400 after forming migration isolation pits 430. To form the migration isolation pits 430, the process can include stripping the second masking layer 470 (FIG. 4D), depositing a third masking layer 480 over the dielectric layer 416, and etching the third masking layer 480 to include a plurality of openings 482. The openings 482 in the third masking layer 480 are only formed in locations corresponding to the migration isolation pits 430 (e.g., only over the second openings 452b (FIG. 4C) in the semiconductor die 400). Once the openings 482 in the third masking layer 480 are formed, the process can include filling the openings 482 with a non-conductive material. As discussed above, the non-conductive material can include various carbon-free (e.g., Silicon Oxide, Silicon Nitride, and/or the like) and/or low-carbon (e.g., Silicon Carbon Nitride with reduced carbon content) dielectric materials. The absence (or low concentration) of the carbon allows the dielectric to absorb conductive materials migrating away from the bond pads 420 when the semiconductor die 400 is stacked with and bonded to other semiconductor dies.

As a result of the process discussed above, as illustrated in FIGS. 4D and 4E, the bond pads 420 and the migration isolation pits 430 each extend to a second depth D₂ beneath an uppermost surface of the dielectric layer 416. As further illustrated in FIGS. 4D and 4E, the second depth D₂ is larger than a thickness of the dielectric layer 416 such that the bond pads 420 and the migration isolation pits 430 each extend at least partially into the base substrate 412. In various embodiments, the second depth D₂ is at least about 20 nanometers (nm) and/or between about 20 nm and about 30 nm. The minimum depth can help ensure that sufficient conductive material is available in the bond pads 420 to avoid errors in manufacturing and/or to help ensure the migration isolation pits 430 can absorb a sufficient amount of conductive material.

FIG. 4F illustrates the semiconductor die 400 after stripping the third masking layer 480 (FIG. 4E) from the semiconductor die 400. As a result of the process discussed above, the semiconductor die 400 includes a plurality of bond pads 420 and a plurality of migration isolation pits 430. Further, each pair of adjacent bond pads 420 is separated by at least one of the migration isolation pits 430. As further illustrated in FIG. 4F, an outer surface of each of the bond pads 420 and each of the migration isolation pits 430 can be generally coplanar with an upper surface 417 of the dielectric layer 416. As a result, the semiconductor die 400 can have a generally flat bonding surface for bonding to other semiconductor dies.

It will be understood that although FIGS. 4B and 4C illustrates a process for etching the dielectric layer 416 to form the first and second openings 452a, 452b at the same time, the processes disclosed herein are not so limited. In some embodiments, a first etching process can be executed to form the first openings 452a (e.g., by depositing and patterning a first masking layer, then etching the dielectric layer 416 through the first masking layer) and a second etching process can be executed to form the second openings 452b (e.g., by depositing and patterning a second masking layer, then etching the dielectric layer 416 through the second masking layer). In such embodiments, the first and second etching processes can be executed in any suitable order. It will further be understood that the processes described with respect to FIGS. 4D-4F can be executed in any suitable order (e.g., to form the migration isolation pits 430 before forming the bond pads 420). In some embodiments, the bond pads 420 and the migration isolation pits can be formed completely independent from each other. For example, a manufacturing process can form the second openings 452b (FIG. 4C) and the migration isolation pits 430 (FIG. 4E), then form the first openings 452a and the bond pads 420 (FIG. 4D). In another example, a manufacturing process can form the first openings 452a and the bond pads 420 (FIG. 4D), then form the second openings 452b (FIG. 4C) and the migration isolation pits 430 (FIG. 4E).

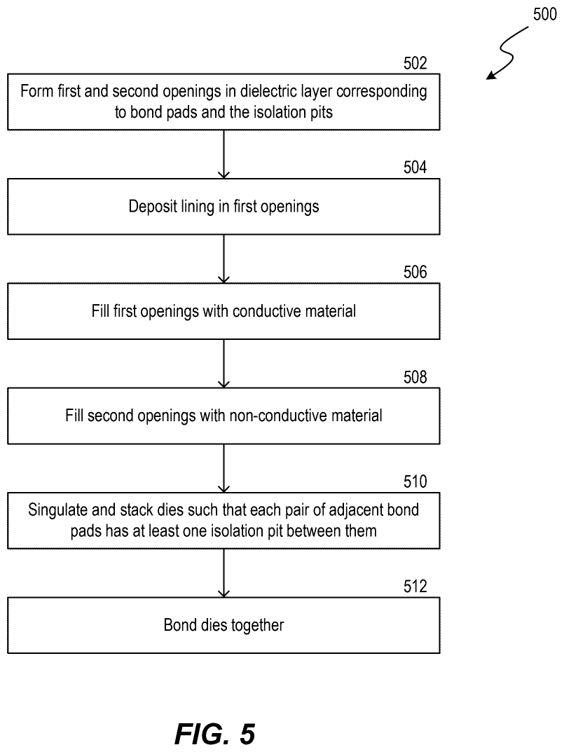

FIG. 5 is a flow diagram of a process 500 for manufacturing a stacked semiconductor device in accordance with embodiments of the present technology. More specifically, the process 500 illustrated in FIG. 5 generally follows the process illustrated above with reference to FIGS. 4A-4F to form migration isolation pits within semiconductor dies for the stacked semiconductor device. The process 500 can be executed partially (or fully) at the wafer level and/or at an individual die level. The process 500 is illustrated as a set of steps or blocks 502, 504, 506, 508, 510, and 512. All or a subset of one or more of these blocks 502, 504, 506, 508, 510, and 512 can be executed in accordance with the discussion (e.g., of FIGS. 4A-4F) above to produce a semiconductor device of the type discussed above with reference to FIG. 1. Indeed, several of the blocks 502, 504, 506, 508, 510, and 512 of the process 500 are described below with reference to FIGS. 4A-4F.

It will be understood that the process 500 of FIG. 5 can be a subprocess of a broader process for manufacturing the stacked semiconductor device. For example, the process 500 can be executed after executing various other processes to create TSVs, metallization layers, active circuits, and/or the like in a semiconductor substrate. In another example, the process 500 can be executed before various other packaging processes, such as bonding a die stack to a package substrate, interposer, and/or other suitable substrate, encasing the die stack in a mold material, and/or the like. Further, it will be understood that the process 500 of FIG. 5 can be executed in a single manufacturing apparatus and/or split between different manufacturing apparatuses. Purely by way of example, a first apparatus can execute blocks 502, 504, 506, and 508 at a wafer level. The wafer can then be transported and singulated before executing blocks 510 and 512 in a second apparatus. Said another way, different apparatuses can execute different portions of the process 500 discussed below.

The process 500 begins at block 502 with forming first and second openings in a dielectric layer. Similar to the discussion above with reference to FIGS. 4B and 4C, the process 500 at block 502 can include depositing a patterned first mask over the dielectric layer and etching the dielectric layer through the first mask. The resulting first openings (e.g., the first openings 452a of FIG. 4C) can correspond to bond pad locations. For example, the first openings can be generally vertically aligned with an upper surface of a TSV and/or other metallization feature in a base substrate of the semiconductor die. The second openings (e.g., the second openings 452b of FIG. 4C) can correspond to migration isolation pits. For example, the second openings can include one or more trenches that are positioned between adjacent first openings. In some embodiments, each of the first openings is fully surrounded by at least one of the second openings. In some embodiments, the second openings include a trench segment positioned along a direct path between adjacent first openings. In some embodiments, the second openings are not positioned between each pair of adjacent first openings. For example, the second openings can be positioned between alternating pairs of adjacent first openings. In this example, when dies are stacked and bonded, the dies can be positioned such that the migration isolation pits in a first die are offset from the migration isolation pits in a second die. As a result, each pair of adjacent bond pads can have a migration isolation pit positioned therebetween on either the first die or the second die.

Although the process 500 of FIG. 5 (and the process discussed above with reference to FIGS. 4A-4F) have been discussed primarily in the context of forming the first and second openings generally simultaneously (e.g., via the same etching process), it will be understood that the processes disclosed herein are not so limited. For example, the process 500 can include a subblock for forming the first openings as well as a subblock for forming the second openings such that the first and second openings are formed sequentially. In another example, the process 500 can form a first portion of the first and/or second openings generally simultaneously with the second and/or first openings, respectively, then form a second portion individually. In a specific, non-limiting example, the second openings can be formed to a greater depth than the first openings. In this example, the process 500 can pause during an etching step of block 502 to deposit a supplementary mask over the first openings, then continue etching to further form the second openings.

At block 504, the process 500 includes depositing a lining in the first openings. Similar to the discussion above, the process 500 at block 504 can include stripping and/or otherwise removing the first mask and depositing a patterned second mask over the dielectric layer. The second mask can include openings (e.g., the openings 472 of FIG. 4D) that generally correspond to the first openings in the dielectric layer while covering (or filling) the second openings in the dielectric layer. The lining can include a barrier layer (e.g., the barrier layer 424 of FIG. 4D) to help prevent a conductive material of the bond pads from migrating out of the first openings during later processes. In some embodiments, the lining includes a seed layer to help form the bond pads during a later deposition process.

At block 506, the process 500 includes filling the first openings with a conductive material. Filling the first openings can include various different deposition, etching, and/or grinding processes. The conductive material can include copper, tin, solder, gold, and/or any other suitable conductive material. The conductive material bonds to the lining in the first opening, thereby forming a bond pad in each of the first openings. In some embodiments, the process 500 at block 506 fills the first openings to a level that is coplanar (or generally coplanar) with an upper surface of the dielectric material. In some embodiments, the process 500 at block 506 includes a planarization process to remove excess conductive material such that the upper surface of the bond pads is coplanar (or generally coplanar) with the upper surface of the dielectric material.

At block 508, the process 500 includes filling the second openings with a non-conductive material. Similar to the discussion above, the process 500 at block 508 can include stripping and/or otherwise removing the second mask (if remaining after block 506) and depositing a patterned third mask over the dielectric layer and the bond pads. The third mask can include openings (e.g., the openings 482 of FIG. 4E) that generally correspond to the second openings in the dielectric layer, allowing the second openings to be filled by any suitable deposition process. Further, similar to the discussion above, the non-conductive material can include a carbon-free and/or low-carbon dielectric material. In contrast to dielectrics typically used in the dielectric layer, the absence (or low concentration) of carbon allows the non-conductive material to absorb conductive materials rather than allowing them to migrate across the non-conductive material. As a result, the non-conductive material deposited into the second openings can mitigate conductive material migration (e.g., stress and/or electromigration) during later processes and/or operation of the resulting semiconductor device. Further, similar to the discussion above, the process 500 at block 508 can fill the second openings to a level that is coplanar (or generally coplanar) with an upper surface of the dielectric material and/or include a planarization process to remove excess non-conductive material.

At block 510, the process 500 includes singulating and/or stacking the dies such that each pair of adjacent bond pads has at least one migration isolation pit positioned between the bond pads. In some embodiments, the migration isolation pits are mirrored between the stacked dies such that there is a migration isolation pit on both a first die and a second die stacked on the first die (and so on). In some embodiments, as discussed above, the migration isolation pit positioned between adjacent bond pads is on only the first die or only the second die. In some embodiments, the singulation and/or stacking process includes various planarization and/or cleaning processes to help create a clean, flat surface at the bonding interface between each of the stacked dies. In some embodiments, the dies are stacked at the wafer level and singulated after a bonding process in block 512.

At block 512, the process 500 includes bonding the dies together. The bonding process at block 512 can include applying heat and/or pressure to generate metal-metal bonds and/or dielectric-dielectric bonds (sometimes referred to collectively as “hybrid bonds”) between each of the stacked dies. The bonding process at block 512 can generate thermal and/or mechanical stresses in the stacked dies that, in turn, can result in the conductive material in one or more of the bond pads migrating across the bonding interface. As the conductive material migrates, however, it can be absorbed by the migration isolation pits. As a result, the migration isolation pits can help prevent electrical shorts from forming during the bonding process, break lamellas of the conductive material to allow the dielectric layers of the stacked dies to bond together, and/or otherwise improve the quality of the resulting stacked semiconductor device.

In some embodiments, the process 500 stacks and bonds dies one level at a time. In such embodiments, the process 500 can return to block 510 to stack a third die over the second die and then bond the third die to the second die at block 512. The process 500 can then loop through blocks 510 and 512 until the stacked semiconductor device is complete. In some embodiments, the process 500 stacks and bonds multiple (or all) levels in a single pass through blocks 510 and 512.

Although the blocks 502, 504, 506, 508, 510, and 512 of the process 500 are discussed and illustrated in a particular order, the process 500 illustrated in FIG. 5 is not so limited. In other embodiments, the process 500 can be performed in a different order. In these and other embodiments, any of the blocks 502, 504, 506, 508, 510, and 512 of the process 500 can be performed before, during, and/or after any of the other blocks 502, 504, 506, 508, 510, and 512 of the process 500. For example, all or a subset of block 508 can be executed before blocks 506 and 508 to fill the second openings before filling the first openings. Moreover, a person of ordinary skill in the relevant art will recognize that the illustrated process 500 can be altered and still remain within these and other embodiments of the present technology. For example, one or more blocks 502, 504, 506, 508, 510, and 512 of the process 500 illustrated in FIG. 5 can be omitted and/or repeated in various suitable processes. Additionally, or alternatively, the process 500 can include one or more additional steps not explicitly discussed above (e.g., various back-end-of-line processes, cleaning processes, and/or the like).

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “generally, “approximately,” and “about” are used herein to mean within at least within 10% of a given value or limit. Purely by way of example, an approximate ratio means within 10% of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Various communications links can be used, such as the Internet, a local area network, a wide area network, or a point-to-point dial-up connection. Thus, computer-readable media can comprise computer-readable storage media (e.g., “non-transitory” media) and computer-readable transmission media.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A stacked semiconductor device, comprising:
a first semiconductor die having a first bonding surface, the first semiconductor die comprising:
a first bond pad at the first bonding surface;
a second bond pad at the first bonding surface, wherein the second bond pad is spaced apart from the first bond pad; and
a migration isolation pit at the first bonding surface, wherein the migration isolation pit is positioned between the first bond pad and the second bond pad; and
a second semiconductor die having a second bonding surface, wherein the second semiconductor die is stacked on the first semiconductor die, and wherein the second semiconductor die comprises:
a third bond pad at the second bonding surface, wherein the third bond pad is bonded to the first bond pad of the first semiconductor die; and
a fourth bond pad at the second bonding surface, wherein the fourth bond pad is bonded to the second bond pad of the first semiconductor die.

2. The stacked semiconductor device of claim 1 wherein the migration isolation pit is a first migration isolation pit, wherein the second semiconductor die further comprises a second migration isolation pit at the second bonding surface, and wherein the second migration isolation pit is positioned between the third bond pad and the fourth bond pad.

3. The stacked semiconductor device of claim 1 wherein at least a portion of the first bond pad extends horizontally across a bonding interface between the first semiconductor die and the second semiconductor die and into the migration isolation pit.

4. The stacked semiconductor device of claim 1 wherein the first semiconductor die further comprises a dielectric material at the first bonding surface, and wherein the first bond pad, the second bond pad, and the migration isolation pit are formed into the dielectric material.

5. The stacked semiconductor device of claim 4 wherein the first semiconductor die further comprises a base substrate, and wherein the first bond pad, the second bond pad, and the migration isolation pit are each formed at least partially into the base substrate.

6. The stacked semiconductor device of claim 1 wherein the migration isolation pit has a depth of at least 20 nanometers.

7. The stacked semiconductor device of claim 1 wherein the migration isolation pit comprises:
a trench formed into the first bonding surface; and
a non-conductive material deposited into the trench.

8. The stacked semiconductor device of claim 7 wherein the non-conductive material is a carbon-free dielectric material.

9. The stacked semiconductor device of claim 1 wherein the migration isolation pit is a first migration isolation pit, wherein the first semiconductor die further comprises a second migration isolation pit at the first bonding surface, and wherein the second migration isolation pit is spaced positioned between the first bond pad and the second bond pad and spaced apart from the first migration isolation pit.

10. The stacked semiconductor device of claim 1 wherein the first bond pad and the second bond pad are ones of a plurality of bond pads, and wherein the migration isolation pit comprises a grid with at least one grid line positioned between each pair of adjacent bond pads in the plurality of bond pads.

11. The stacked semiconductor device of claim 1 wherein the migration isolation pit fully surrounds the first bond pad.

12. A semiconductor die for a stacked semiconductor device, the semiconductor die comprising:
a base substrate;
a first dielectric material deposited over an upper surface of the base substrate;
a pair of bond pads formed into the first dielectric material at the upper surface of the base substrate, the pair of bond pads including a first bond pad and second bond pad spaced apart from the first bond pad;
a trench formed into the first dielectric material at the upper surface of the base substrate between the first bond pad and the second bond pad; and
a second dielectric material deposited into the trench.

13. The semiconductor die of claim 12 wherein the second dielectric material comprises one or more of Silicon Oxide, Silicon Nitride, and/or low-carbon Silicon Carbon Nitride.

14. The semiconductor die of claim 12, further comprising a plurality of metallization features formed within the base substrate, wherein the first bond pad and the second bond pad are each communicably coupled to at least one of the plurality of metallization features.

15. The semiconductor die of claim 12 wherein:
the trench is a first trench;
the semiconductor die further comprises a second trench formed into the first dielectric material at the upper surface of the base substrate between the first bond pad and the second bond pad; and
the second dielectric material is deposited into the first trench and the second trench.

16. The semiconductor die of claim 12 wherein an outer surface of the first dielectric material is coplanar with an outer surface of the second dielectric material.

17. The semiconductor die of claim 12 wherein the first bond pad and the second bond pad each extend to a first depth in the base substrate, wherein the trench extends to a second depth within the base substrate, and wherein the second depth is generally equal to the first depth.

18. A method for manufacturing a stacked semiconductor device, the method comprising:
forming first openings in a first dielectric material deposited over a base substrate of a first die, wherein the first openings expose upper surfaces of metallization features in the first die,
forming second openings in the first dielectric material, wherein the second openings expose the base substrate, and wherein each of the second openings is positioned between a pair of adjacent first openings;
depositing a conductive material in the first openings to form first bond pads in the first openings electrically coupled to the upper surfaces of the metallization features;
depositing a second dielectric material in the second openings, wherein the second dielectric material is different from the first dielectric material such that the second openings create a migration isolation pit between pairs of adjacent first bond pads; and
bonding each of the first bond pads to a corresponding second bond pad of a second die.

19. The method of claim 18 wherein the first openings and the second openings are formed simultaneously.

20. The method of claim 18 wherein bonding each of the first bond pads to the corresponding second bond pad comprises heating the first die and the second die such that a portion of at least one of the first bond pads migrates into a corresponding isolation pit.
